(19) United States
(12) Patent Application Publication
(10) Pub. No.: US 2026/0050006 A1
(43) Pub. Date: Feb. 19, 2026

(54) INSPECTION DEVICE

(71) Applicant: EPISTAR CORPORATION, Hsinchu (TW)

(72) Inventors: Yih-Hua RENN, Hsinchu (TW); Kun-Wei KAO, Hsinchu (TW); Teng-Hui HSIEH, Hsinchu (TW); Chun-Fan WEN, Hsinchu (TW); Yi-Hsuan LIN, Hsinchu (TW); Yu-Siang WANG, Hsinchu (TW)

(21) Appl. No.: 19/300,256

(22) Filed: Aug. 14, 2025

(30) Foreign Application Priority Data
Aug. 15, 2024 (TW) 113130727

(51) Int. Cl. G01R 1/04; G01R 31/28

(52) U.S. Cl. CPC G01R 1/0416; G01R 31/2886

(57) ABSTRACT

An inspection device includes a carrier, an input electrode, a metal layer and a contact electrode. The input electrode is disposed on the carrier. The metal layer includes a fixed portion and an extending portion. The fixed portion is disposed on the carrier, the fixed portion has one end connected to the input electrode, and has another end that extends in a direction far away from the carrier. The extending portion is electrically connected to the another end of the fixed portion, the extending portion is separated from the carrier by a spacing to form a buffer region. The contact electrode is disposed on the extending portion of the metal layer, and electrically connected to the extending portion of the metal layer. The contact electrode has a concave surface facing away from the carrier.

### CROSS-REFERENCE TO RELATED APPLICATIONS

This application claims priority to, and the benefit of, Taiwan Patent Application Number 113130727 filed on Aug. 15, 2024, the entirety of which is hereby incorporated by reference.

### TECHNICAL FIELD

The present disclosure relates to an inspection device, and in particular, to an inspection device having a concave sensing surface.

### DESCRIPTION OF BACKGROUND ART

In the development of the semiconductor industry, to ensure that the integrated circuits meet specifications and quality requirements, tests are often performed on the functions and performance of integrated circuits, including measurements of voltage, current, resistance, and capacitance of the semiconductor components within the integrated circuits. Probe cards are commonly used tools for conducting such tests.

In a probe card, the components that come into contact with the semiconductor devices are called probes. The probes can electrically contact the devices under test to input electrical energy and output the measured signals to the testing equipment.

Probe cards have become indispensable tools in the production process of semiconductor devices. They are used to eliminate non-compliant components, thereby preventing such components from entering subsequent manufacturing processes.

### SUMMARY

The present disclosure provides an inspection device including a carrier, an input electrode, a metal layer, and a contact electrode. The input electrode is disposed on the carrier. The metal layer includes a fixed portion and an extending portion. The fixed portion is disposed on the carrier. A first end of the fixed portion is electrically connected to the input electrode, and a second end of the fixed portion extends in a direction far away from the carrier. The extending portion is electrically connected to the second end, and is separated from the carrier by a spacing to form a buffer region. The contact electrode is disposed on the extending portion, and is electrically connected to the extending portion. The contact electrode has a concave surface facing away from the carrier.

### BRIEF DESCRIPTION OF THE DRAWINGS

The embodiments of the present disclosure can be more fully understood by reading the subsequent detailed description and examples with references made to the accompanying drawings. For clarity, the features in the drawings may not be drawn to actual scale, and certain features may be enlarged or reduced in size. The drawings are described as follows:

FIG. 1 is a cross-sectional view of an inspection device according to one embodiment.

FIG. 2 is a schematic diagram illustrating the use of an inspection device according to one embodiment.

FIG. 3 is a schematic diagram illustrating the use of an inspection device with a convex portion according to one embodiment.

FIGS. 4-9 illustrate a manufacturing process of an inspection device according to one embodiment.

FIG. 10 is a cross-sectional view of an inspection device according to one embodiment.

FIG. 11 is a cross-sectional view of an inspection device according to one embodiment.

FIG. 12 is a cross-sectional view taken along line A-A of FIG. 11.

FIG. 13 is a cross-sectional view of an inspection device according to one embodiment.

FIG. 14 is a cross-sectional view of an inspection device according to one embodiment.

FIG. 15 is a cross-sectional view of an inspection device according to one embodiment.

FIG. 16 is a cross-sectional view taken along line B-B of FIG. 15.

FIG. 17 is a cross-sectional view taken along line C-C of FIG. 15.

FIG. 18 is a cross-sectional view of an inspection device according to one embodiment.

FIG. 19 is a cross-sectional view taken along line D-D of FIG. 18.

FIG. 20 is a cross-sectional view of an inspection device according to one embodiment.

### DETAILED DESCRIPTION OF THE APPLICATION

The present disclosure provides various embodiments for implementing different features. To simplify illustration, specific examples of elements and arrangements are described herein. These examples are provided for illustrative purposes only and are not intended to be limiting. The disclosure may repeat symbols and/or characters of components in different embodiments or examples. This repetition is for simplicity and clarity, and does not indicate a relationship between different embodiments or examples.

In addition, for convenience of description, spatially relative terms such as “below,” “under,” “lower,” “above,” “upper,” “on,” “top,” “bottom,” and the like may be used herein to describe the relationship of one component or feature to another (or other) component or feature as shown in the figures. Spatially relative terms are intended to comprise different orientations of the component in use or operation, in addition to the orientations shown in the figures. The component may be otherwise oriented (e.g., rotated 90 degrees or in other orientations), and the spatially relative descriptions used herein may be interpreted accordingly.

Although this disclosure uses terms such as first, second, or third to describe devices, elements, components, regions, layers, and/or sections, it should be understood that these devices, elements, components, regions, layers, and/or sections are not limited by these terms. These terms are only used to distinguish one device, element, component, region, layer and/or section from another device, element, component, region, layer and/or section and do not imply or indicate any order. These terms do not imply the order of arrangement of one component relative to another component, nor the order of manufacturing processes. Thus, a first device, element, component, region, layer and/or section described below could be referred to as a second device, element, component, region, layer and/or section without departing from the scope of the embodiments of the disclosure.

In the present disclosure, the terms “about,” “approximately,” and “substantially” generally mean +/−20% of the stated value, and more specifically, they may mean +/−10%, +/−5%, +/−3%, +/−2%, +/−1%, or even +/−0.5% of the stated value, as appropriate. It should be noted that the stated value of the present disclosure is an approximate value. That is, when there is no specific description of the terms “about,” “approximately,” or “substantially,” the stated value includes the meaning of “about,” “approximately,” or “substantially”. For example, if a first direction is perpendicular or “substantially” perpendicular to a second direction, the angle between the first direction and the second direction may be between 80 and 100 degrees. If the first direction is parallel or “substantially” parallel to the second direction, the angle between the first direction and the second direction may be between 0 and 10 degrees.

Although the present disclosure is described below through specific embodiments, the inventive principles of the present disclosure may also be applied to other embodiments. Additionally, certain details may be omitted to avoid obscuring the spirit of the disclosure.

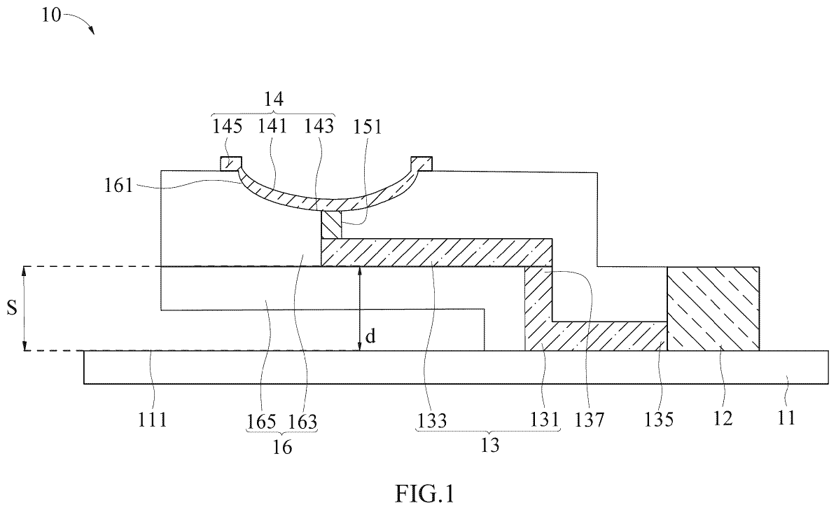

Please refer to FIG. 1. The inspection device 10 includes a carrier 11, an input electrode 12, a metal layer 13, and a contact electrode 14. The input electrode 12 is disposed on a first surface 111 of the carrier 11. The metal layer 13 includes a fixed portion 131 and an extending portion 133. The fixed portion 131 is disposed on the first surface 111, and has a first end 135 and a second end 137 opposite each other. The first end 135 is electrically connected to the input electrode 12. The second end 137 extends in a direction far away from the carrier 11, e.g., upward. The extending portion 133 is electrically connected to the second end 137 of the fixed portion 131. The extending portion 133 is separated from the carrier 11 by a spacing d to form a buffer region S.

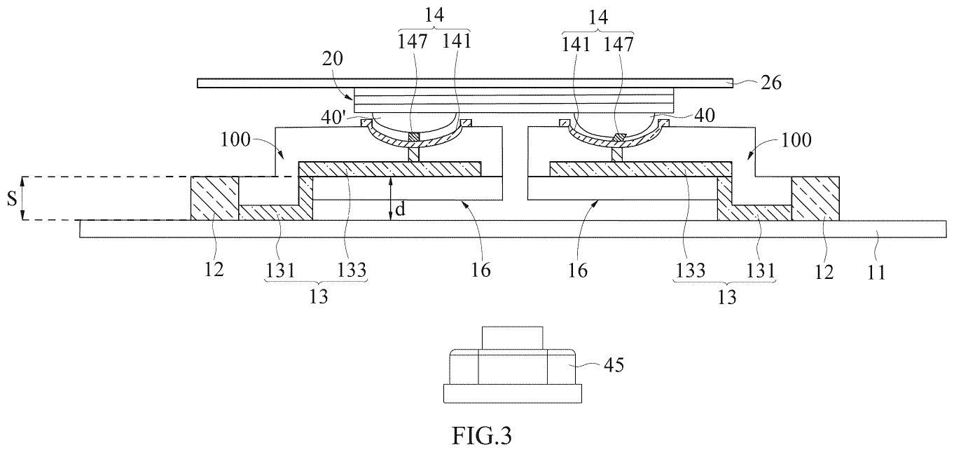

The contact electrode 14 is disposed on and electrically connected to the extending portion 133. The input electrode 12 can be electrically connected to the contact electrode 14 through the metal layer 13. The contact electrode 14 has a concave surface 141 facing away from the carrier 11. The contact electrode 14 is capable of providing power to the electronic component under test when the electronic component under test is placed on the concave surface 141. In one embodiment, the contact electrode 14 has an exposed portion 145 at the outer periphery of the concave surface 141. In another embodiment, the contact electrode 14 has a convex portion 147 protruding from the concave surface 141 (as shown in FIG. 3).

In one embodiment, the inspection device 10 can be used with external equipment to inspect the characteristics of electronic components, thereby eliminating those electronic components that do not meet the specifications and thus improving the production yield.

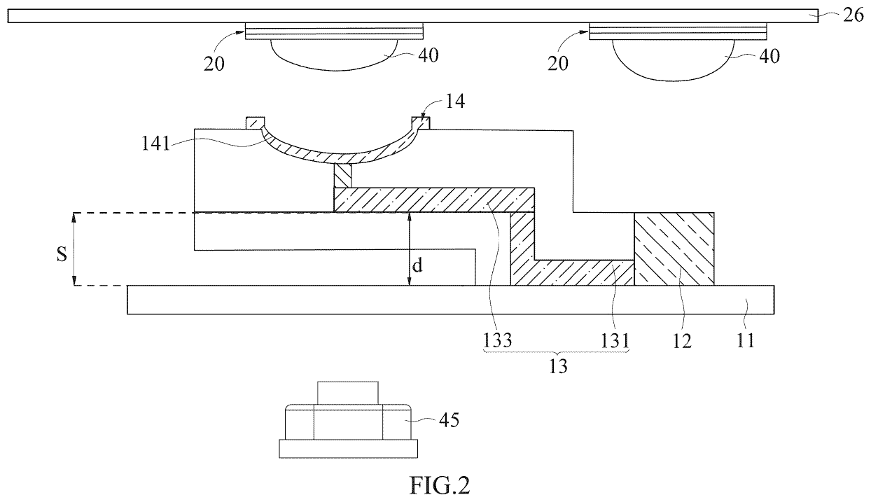

FIG. 2 is a schematic diagram illustrating the use of an inspection device in accordance with one embodiment of the present disclosure. As shown in FIG. 2, the inspection device 10 is used to inspect a light-emitting diode (LED) 20. A plurality of LEDs 20 is placed on a substrate. The LED 20 has an electrode 40 to be tested, wherein the electrode 40 faces the concave surface 141 of the contact electrode 14. The input electrode 12 can be electrically connected to an external power supply (not shown) to provide electrical power to the LED 20 via the metal layer 13 and the contact electrode 14. The LED 20 generates an optical and/or electrical signal after receiving electrical power.

In one embodiment, the electrode 40 of the LED 20 has a convex surface, which can be part of a spherical, hemispherical, parabolic, hyperbolic, or other curved surface. The concave surface 141 of the contact electrode 14 can contact the convex surface of the electrode 40. The maximum depth of the concave surface 141 is less than or equal to the maximum height of the convex surface, and the maximum width of the concave surface 141 is greater than or equal to the maximum width of the convex surface.

Compared to a planar contact electrode (not shown), the contact electrode 14 can confine the convex surface of the electrode 40 within the concave surface 141. This not only increases the contact area (or reduces the contact resistance) between the contact electrode 14 and the electrode 40, but also prevents the contact electrode 14 from sliding on the electrode 40, thereby extending the service life of the inspection device 10.

Referring to FIG. 2, in one embodiment, there is a buffer region S between the extending portion 133 and the carrier 11. When the contact electrode 14 contacts the electrode 40, the concave surface 141 bears a force, causing the extending portion 133 to bend downward, thereby reducing the buffer region S. If the micro LEDs 20 to be tested have various heights, the buffer region S allows the extending portion 133 to bend in response to the height variations of the micro LEDs 20. This prevents excessive pressure between the micro LEDs 20 and the contact electrode 14, thereby avoiding damage to the contact electrode 14 and/or the electrode 40.

In one embodiment, the concave surface 141 of the contact electrode 14 and the convex surface of the electrode 40 have similar contours. In one embodiment, the concave surface 141 is an inner surface of an object, while the convex surface is the outer surface of that object. In one embodiment, the contours of the concave surface 141 of the contact electrode 14 and the convex surface of the electrode 40 are part of a spherical, hemispherical, parabolic, hyperbolic, or other curved surface. In one embodiment, the maximum diameter of the concave surface of the contact electrode 14 is slightly larger than the maximum diameter of the convex surface of the electrode 40, allowing the electrode 40 to be placed within the contact electrode 14 without easily slipping out. In one embodiment, if the maximum diameter of the electrode 40 is 250 micrometers, the diameter of the concave surface of the contact electrode 14 is 251 to 260 micrometers.

Referring to FIGS. 1 and 2, in one embodiment, the contact electrode 14 has an exposed portion 145 at the periphery of the concave surface 141. If the maximum diameter of the electrode 40 is greater than the maximum diameter of the concave surface 141, the electrode 40 contacts the exposed portion 145 without contacting the lowest point of the concave surface 141.

Referring to FIG. 3, in one embodiment, the contact electrode 14 has a convex portion 147 protruding from the concave surface 141. The convex portion 147 is a metal block formed on the extending portion 133 of the metal layer 13 and extends upward in a direction far away from the carrier 11. When the electrodes 40, 40′ are in contact with the convex portions 147, the input electrode 12 can supply electrical power provided by an external power source to the micro LED 20 through the convex portion 147, thereby causing the micro LED 20 to generate optical and electrical signals.

In one embodiment, the inspection device 10 has multiple contact electrodes 14, which can simultaneously measure the two electrodes 40 and 40′ of a single micro LED 20 (as shown in FIG. 3), or the two electrodes 40 and 40′ of different micro LEDs 20 (not shown).

In one embodiment, the convex portion 147 is made of an elastic metal material. When the convex portion 147 of the contact electrode 14 contacts the taller electrode 40′, the elastic convex portion 147 can be more firmly fixed on the convex surface of the electrode 40 and is less likely to scratch the convex surface of the electrode 40. The diameter of the convex portion 147 and the curvature of the tip of the convex portion 147 can be adjusted as needed.

Referring to FIG. 1, in one embodiment, the inspection device 10 includes an insulating layer 16 that covers the metal layer 13. The insulating layer 16 has a recessed region 161 for accommodating the contact electrode 14. The side of the contact electrode 14 opposite the concave surface 141 forms an abutting surface 143, and the contact electrode 14 abuts against the insulating layer 16 with the abutting surface 143. In one embodiment, there is a conductive path 151 within the insulating layer 16. One end of the conductive path 151 is connected to the contact electrode 14, and the other end is connected to the extending portion 133 of the metal layer 13. The conductive path 151 can be filled with metal and/or other conductive materials, thereby electrically connecting the contact electrode 14 and the extending portion 133.

In one embodiment, the insulating layer 16 includes a first insulating layer 163 and a second insulating layer 165. The first insulating layer 163 covers the upper and side surfaces of the extending portion 133 of the metal layer 13, while the second insulating layer 165 covers the lower surface of the extending portion 133. A spacing d is present between the extending portion 133 and the carrier 11, forming a buffer region S. The second insulating layer 165 is located within the buffer region S, and a spacing between the lower surface of the second insulating layer 165 and the carrier 11 is less than the spacing d but greater than 0. The extending portion 133, sandwiched between the first insulating layer 163 and the second insulating layer 165, is able to bend toward the carrier 11.

In one embodiment, the first insulating layer 163 and the second insulating layer 165 have different materials. The Young's modulus of the material of the second insulating layer 165 is greater than that of the first insulating layer 163. In one embodiment, the Young's modulus of the material of the first insulating layer 163 is 10 GPa or less, while the Young's modulus of the material of the second insulating layer 165 is greater than that of the material of the first insulating layer 163. When the contact electrode 14 is subjected to a downward force, the second insulating layer 165 can support the extending portion 133 of the metal layer 13, preventing the extending portion 133 from breaking due to excessive force.

In one embodiment, the material of the insulating layer 16 is poly(methyl methacrylate) (PMMA), acrylonitrile butadiene styrene (ABS), nylon polyamide (PA), polycarbonate (PC), polyethylene (PE), polyoxymethylene (POM), polypropylene (PP), polystyrene (PS), epoxy resin (EPO), silicone, or a molding material composed of any combination thereof.

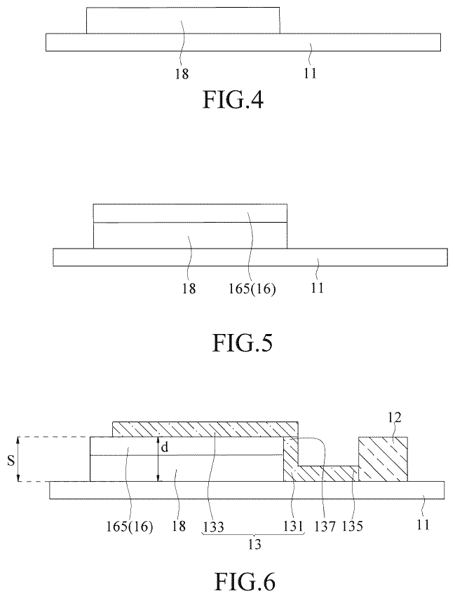

FIGS. 4-9 illustrate a manufacturing process of the inspection device 10 shown in FIG. 1. First, as shown in FIG. 4, a sacrificial layer 18 is disposed on the carrier 11. The material of the sacrificial layer 18 can be an oxide such as silicon oxide, silicon oxynitride, or a photoimageable dielectric (PID) that can be patterned. Referring to FIG. 5, a second insulating layer 165 is formed above the sacrificial layer 18, and the second insulating layer 165 can also be a photoimageable dielectric material that can be patterned. In one embodiment, the second insulating layer 165 is formed using methods such as metal-organic chemical vapor deposition (MOCVD) or physical vapor deposition (PVD).

Referring to FIG. 6, an input electrode 12 and a metal layer 13 are disposed on the carrier 11 and above the second insulating layer 165. The input electrode 12 is located on the carrier 11 and is connected to the metal layer 13. The fixed portion 131 of the metal layer 13 has two ends: one end is connected to the input electrode 12, and the other end extends far away from the carrier 11 and is electrically connected to the extending portion 133. The extending portion 133 is disposed on the second insulating layer 165. The fixed portion 131 of the metal layer 13 is located between the second insulating layer 165 and the input electrode 12. In one embodiment, the metal layer 13 is formed from copper, aluminum, tantalum, tungsten, hafnium, beryllium, or other metals or their alloys, and can be formed on the carrier 11 and the second insulating layer 165 using methods such as MOCVD or PVD.

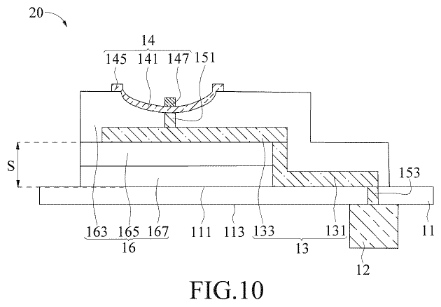

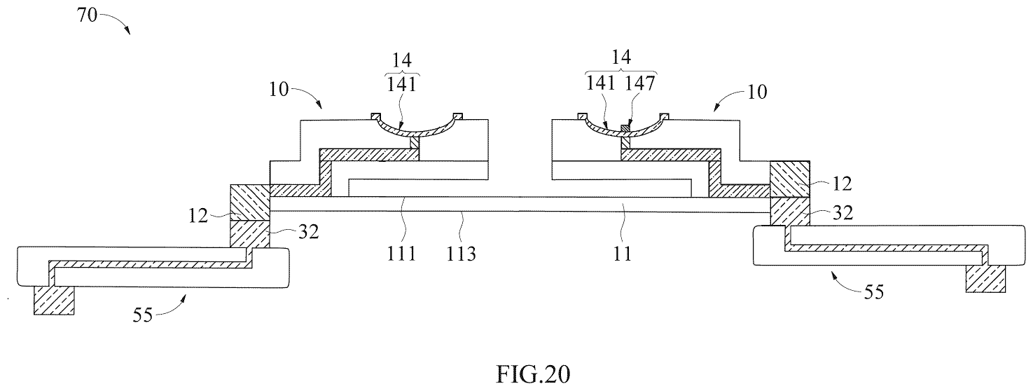

In one embodiment, the input electrode 12 can also be located on the side or below the carrier 11 (as shown in FIGS. 10 and 20). Referring to FIG. 10, the input electrode 12 is located underneath the carrier 11, and the input electrode 12 and the fixed portion 131 are electrically connected through a conductive path 153.

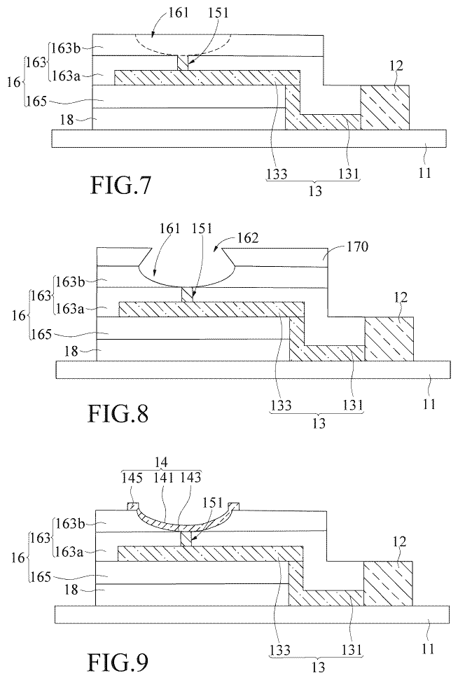

Referring to FIG. 7, a first insulating layer 163 is formed on the metal layer 13. The first insulating layer 163 includes a perforated layer 163a and an electrode layer 163b. The perforated layer 163a is located above the extending portion 133, and the conductive path 151 is formed within the perforated layer 163a. The electrode layer 163b is formed on the perforated layer 163a. A recessed region 161 (as indicated by dashed lines in the figure) is formed in the electrode layer 163b at a location corresponding to the conductive path 151. The first insulating layer 163 and the second insulating layer 165 completely encapsulate the metal layer 13. The first insulating layer 163 is made of a photoimageable dielectric material. The recessed region 161 is formed by etching, grayscale masks, laser writing, or nanoimprinting.

Referring to FIG. 8, a recessed region 161 is formed in a photoresist 170. In one embodiment, a photoresist 170 is formed on the first insulating layer 163 (electrode layer 163b), and an etching space 162 is formed in the photoresist 170. The etching space 162 has an opening at a top and a bottom that are opposite to each other. The projected area of the bottom is larger than that of the opening, forming a space that is narrow at the top and wide at the bottom. After being etched by an etchant, the etching space 162 becomes the recessed region 161. In another embodiment, the recessed region 161 is formed in the first insulating layer 163 using grayscale lithography.

Referring to FIG. 9, a contact electrode 14 is formed on the recessed region 161. The contact electrode 14 is made of metal and is formed only on the recessed region 161. The contact electrode 14 and the recessed region 161 have similar contours. Finally, the sacrificial layer 18 beneath the first insulating layer 163 is removed, forming a buffer region S between the first insulating layer 163 and the carrier 11 as shown in FIG. 1.

FIG. 10 is a cross-sectional view of an inspection device 20 according to another embodiment. In the inspection device 20, the insulating layer 16 includes a third insulating layer 167. One side of the third insulating layer 167 is in contact with the second insulating layer 165, and the other side is in contact with the carrier 11. In other words, the second insulating layer 165 and the third insulating layer 167 completely fill the buffer region S. The third insulating layer 167 and the first insulating layer 163 can be made of the same or different materials. If the third insulating layer 167 and the first insulating layer 163 are made of different materials, the Young's modulus of the third insulating layer 167 can be less than that of the second insulating layer 165. In one embodiment, both the third insulating layer 167 and the first insulating layer 163 are made of materials with a Young's modulus less than or equal to 10 GPa.

As shown in FIG. 10, the buffer region S is completely filled with the second insulating layer 165 and the third insulating layer 167. The second and third insulating layers provide improved support for the extending portion 133, enabling it to withstand the force applied to the contact electrode 14. If the third insulating layer 167 has a smaller Young's modulus than the second insulating layer 165, the third insulating layer 167 is more easily deformed along with the bending of the extending portion 133 when force is applied to the contact electrode 14. When the force is released, the third insulating layer 167 can return to its original shape and assist in restoring the extending portion 133 to its pre-bent position. In one embodiment, the first insulating layer 163, the second insulating layer 165, and the third insulating layer 167 have the same Young's modulus, for example, less than or equal to 10 GPa.

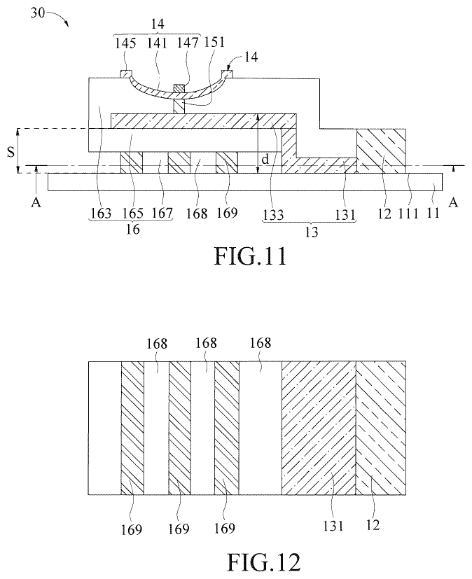

FIG. 11 is a cross-sectional view of an inspection device 30 in which the insulating layer 16 includes hollow portions according to another embodiment. In one embodiment, the third insulating layer 167 includes a plurality of interlaced hollow portions 168 and a plurality of support portions 169. In some embodiments, the height of the hollow portions 168 is less than the spacing d and is equal to the spacing between the lower surface of the third insulating layer 167 and the upper surface of the carrier 11. The two ends of each support portion 169 are connected to the carrier 11 and the second insulating layer 165, respectively. Generally, the greater the number of hollow portions 168, the more easily the third insulating layer 167 deforms under force. Therefore, by adjusting the configuration of the hollow portions 168 and support portions 169, such as the ratio of their numbers or areas, the displacement of the contact electrode 14 under force can be changed.

FIGS. 11 to 19 show multiple embodiments of inspection devices in which the third insulating layer 167 includes hollow portions 168 of various shapes. The third insulating layer 167 has one or more hollow portions 168, and multiple hollow portions 168 are independent and not connected to each other. FIG. 12 is a cross-sectional view taken along line A-A of FIG. 11. As shown in FIG. 12, both the hollow portions 168 and support portions 169 are elongated strips. The three support portions 169 have the same width, while the four hollow portions 168 have different widths. However, the disclosure is not limited to this.

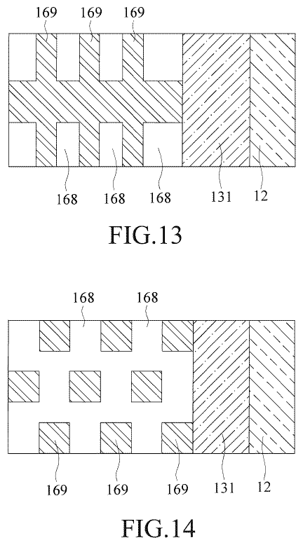

As shown in FIG. 13, the support portions 169 are arranged in a branch pattern, and multiple hollow portions 168 are separated by a single support portion 169. As shown in FIG. 14, the multiple support portions 169 are distributed in an island pattern and are separated by a single hollow portion 168.

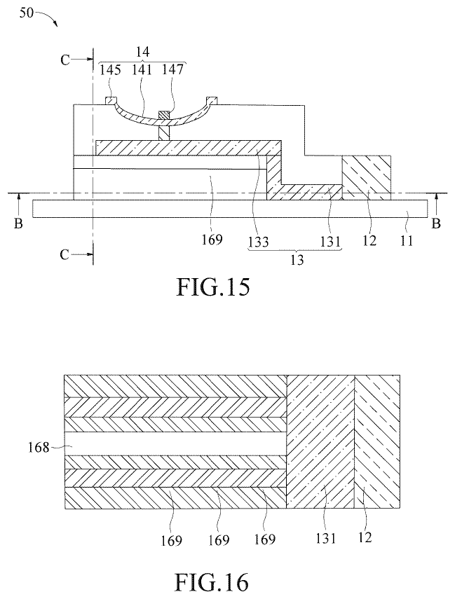

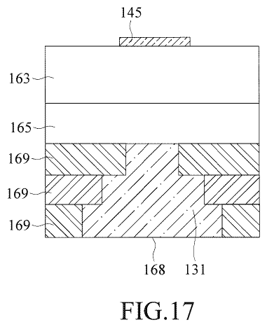

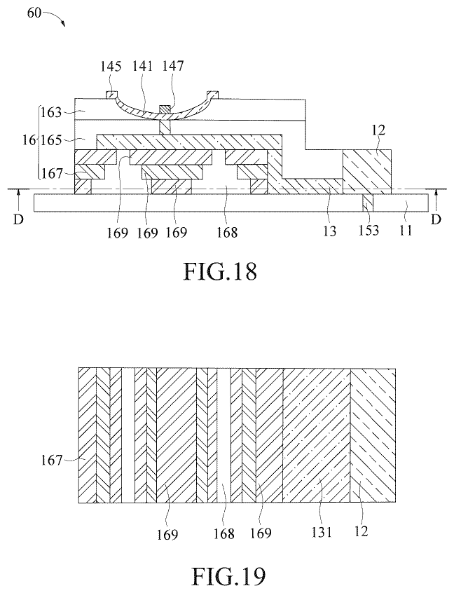

FIG. 15 shows a cross-sectional view of an inspection device 50 with step-shaped support portions 169. FIG. 16 is a cross-sectional view taken along line B-B of FIG. 15, and FIG. 17 is a cross-sectional view taken along line C-C of FIG. 15. As shown in FIGS. 16 and 17, two support portions 169 are separated by a hollow portion 168. The width of a support portion 169 gradually decreases from top to bottom, while the width of the hollow portion 168 gradually increases from top to bottom. FIG. 18 shows a cross-sectional view of an inspection device 60 with step-shaped support portions 169, and FIG. 19 is a cross-sectional view taken along line D-D of FIG. 18. As shown in FIGS. 18 and 19, three support portions 169 are separated by two hollow portions 168. The width of a support portion 169 gradually decreases from top to bottom, and the width of a hollow portion 168 gradually increases from top to bottom.

Referring again to FIG. 2, in one embodiment, both the carrier 11 and the insulating layer 16 are made of materials that are penetrable by visible light. The carrier 11 is made of a transparent bulk material such as sapphire, glass, or quartz. The insulating layer 16 is made of an oxide such as silicon oxide, silicon oxynitride, or a patternable transparent photoimageable dielectric material. In this way, the user can view the micro LED 20 from below the carrier 11. In one embodiment, a camera 45 is placed below the carrier 11 to identify the micro LED 20. This configuration ensures that the electrode 40 to be measured and the micro LED 20 are aligned with each other during the measurement process. In another embodiment, the light emitted by the micro LED 20 can pass through the carrier 11 and the insulating layer 16 and be received by a light receiving device, such as the camera 45, placed below the carrier 11.

Referring to FIG. 3 again, in one embodiment, multiple inspection devices 100 can be disposed on the carrier 11. The input electrode 12 in the inspection devices 100 is disposed on the carrier 11. One end of the fixed portion 131 of the metal layer 13 is electrically connected to the input electrode 12, and the extending portion 133 is separated from the carrier 11 by a spacing d, forming a buffer region S. The contact electrode 14 is disposed on the extending portion 133 of the metal layer 13 and has a concave surface 141. As shown in FIG. 3, the micro LED 20 is a horizontal micro LED, and the two electrodes 40 and 40′ under test are located on the same side. Both electrodes 40 and 40′ can be connected to the two contact electrodes 14. The gap between the contact electrodes 14 is not filled with the insulating layer 16 or is filled with a transparent material, allowing the micro LED 20 to be visible. With this configuration, the position of the micro LED 20 (the device under test) can be identified through the gap during the measurement process, thus enabling more accurate alignment of the micro LED 20 and the electrodes 40, 40′ to be tested. In another embodiment, the light emitted by the micro LED 20 can pass through the gap and be received by the camera 45.

FIG. 20 shows a cross-sectional view of an inspection device 70 according to another embodiment. The carrier 11 has a first surface 111 facing the contact electrode 14 and a second surface 113 facing downward. The input electrode 12 is located on the side of the carrier 11, and above the upper surface 111 (as shown on the right in the figure) or below the lower surface 113 (as shown on the left in the figure). In both configurations, the input electrode 12 has a lower surface that is connected to a flex-printed circuit board (FPCB) 55. In addition, as shown in FIG. 20, the contact electrodes 14 on the left and right respectively illustrate two embodiments, which can be implemented individually or in combination. The contact electrode 14 on the left has a concave surface 141, while the contact electrode 14 on the right has both a concave surface 141 and a convex portion 147.

In one embodiment, the lower surface of the input electrode 12 and the upper surface of the connection end 32 of the FPCB 55 are joined by solder (not shown). In another embodiment, the lower surface of the input electrode 12 and the upper surface of the connection end 32 of the FPCB 55 are connected by a tin-containing layer (not shown), wherein the tin-containing layer is first formed on the lower surface of the input electrode 12 and/or the upper surface of the connection end 32 of the FPCB 55, and can be heated by laser to connect the input electrode 12 and the connection end 32. In addition, the tin-containing layer can be covered by an insulating material to protect the tin-containing layer or to increase the bonding strength between the input electrode 12 and the connection end 32 of the FPCB 55.

In summary, the use of a contact electrode with a concave surface to measure semiconductor devices can reduce damage to the semiconductor devices and also reduce the frequency of replacing contact electrodes and lower the cost of measurement during the process.

Although some embodiments of the present disclosure and their advantages have been described in detail, various changes, substitutions and alterations may be made herein without departing from the spirit and scope of the disclosure as defined by the appended claims.

What is claimed is:

1. An inspection device, comprising:
a carrier;
an input electrode, disposed on the carrier;
a metal layer, comprising:
a fixed portion, disposed on the carrier, and having a first end and a second end, the first end being electrically connected to the input electrode, the second end extending in a direction far away from the carrier; and
an extending portion, electrically connected to the second end, and separated from the carrier by a spacing to form a buffer region; and
a contact electrode, having a concave surface facing away from the carrier, and disposed on and electrically connected to the extending portion.

2. The inspection device of claim 1, further comprising an insulating layer covering the metal layer, wherein the contact electrode abuts against the insulating layer.

3. The inspection device of claim 2, wherein the insulating layer fills the buffer region.

4. The inspection device of claim 2, wherein the carrier and the insulating layer are capable of being passed through by a visible light.

5. The inspection device of claim 2, wherein, the extending portion has a first side facing away from the carrier, and a second side facing the carrier, the insulating layer comprises a first insulating layer covering the firs side, and a second insulating layer covering the second side and having a Young's modulus greater than that of the first insulating layer.

6. The inspection device of claim 5, wherein the Young's modulus of the first insulating layer is less than or equal to 10 GPa.

7. The inspection device of claim 5, wherein the insulating layer further comprises a third insulating layer connected to the second insulating layer and the carrier, and the Young's modulus of the second insulating layer is greater than that of the third insulating layer.

8. The inspection device of claim 7, wherein the third insulating layer comprises a plurality of hollow portions.

9. The inspection device of claim 8, wherein at least one of the plurality of hollow portions has a height in a direction perpendicular to the carrier, and the height is less than the spacing.

10. The inspection device of claim 2, wherein the insulating layer has a recessed region for accommodating the contact electrode.

11. The inspection device of claim 10, wherein the contact electrode has an exposed portion not located within the recessed region.

12. The inspection device of claim 11, wherein the exposed portion is disposed at a periphery of the concave surface.

13. The inspection device of claim 2, further comprising a conductive path disposed within the insulating layer, and electrically connected to the contact electrode and the extending portion.

14. The inspection device of claim 1, wherein the contact electrode has a convex portion protruding from the concave surface.

15. The inspection device of claim 1, further comprising a conductive path connected to the contact electrode and the extending portion.
